(19) United States
(12) Patent Application Publication
(10) Pub. No.: US 2013/0061801 A1
(43) Pub. Date: Mar. 14, 2013

(54) METHOD FOR MANUFACTURING SILICON CARBIDE CRYSTAL

(71) Applicants: Shinsuke FUJIWARA, Itami-shi (JP); Shin HARADA, Osaka-shi (JP); Taro NISHIGUCHI, Itami-shi (JP); Hiroki INOUE, Itami-shi (JP); Naoki OOI, Itami-shi (JP)

(72) Inventors: Shinsuke FUJIWARA, Itami-shi (JP); Shin HARADA, Osaka-shi (JP); Taro NISHIGUCHI, Itami-shi (JP); Hiroki INOUE, Itami-shi (JP); Naoki OOI, Itami-shi (JP)

(73) Assignee: SUMITOMO ELECTRIC INDUSTRIES, LTD., Osaka-shi (JP)

(21) Appl. No.: 13/566,070

(22) Filed: Aug. 3, 2012

Related U.S. Application Data
(60) Provisional application No. 61/534,589, filed on Sep. 14, 2011.

(30) Foreign Application Priority Data
Sep. 14, 2011 (JP) 2011-200071

(51) Int. Cl. C30B 23/02

(52) U.S. Cl. 117/105

(57) ABSTRACT

Provided is a method for manufacturing a silicon carbide crystal, including the steps of: placing a seed substrate and a source material for the silicon carbide crystal within a growth container; and growing the silicon carbide crystal with a diameter of more than 4 inches on a surface of the seed substrate by a sublimation method, in the step of growing, a pressure within the growth container being changed from a predetermined pressure, at a predetermined change rate.

### BACKGROUND OF THE INVENTION

1. Field of the Invention

The present invention relates to a method for manufacturing a silicon carbide crystal by a sublimation method.

2. Description of the Background Art

In recent years, a silicon carbide (SiC) crystal has begun to be adopted as a semiconductor substrate used to manufacture a semiconductor device. SiC has a band gap larger than that of silicon (Si), which has been more commonly used. Hence, the semiconductor device using SiC has advantages such as high breakdown voltage, low ON resistance, and less deterioration in characteristics under a high temperature environment, and has been attracting attention.

Such a SiC crystal is grown, for example, by a sublimation method as a vapor deposition method. For example, Patent Literature 1 (Japanese Patent National Publication No. 2008-515749) discloses a method for manufacturing a SiC wafer by forming a SiC boule by a sublimation method, slicing and polishing it, and further etching it using molten KOH. According to the method described in Patent Literature 1, a SiC wafer having a diameter of at least 100 mm (4 inches) and a micropipe density of less than about 25 cm⁻² can be manufactured.

### SUMMARY OF THE INVENTION

Recently, there has been a demand for a large semiconductor substrate in order to efficiently manufacture a semiconductor device. However, as described in Patent Literature 1, the size of a SiC substrate is at most about 100 mm (4 inches) on an industrial basis, and it is actually not possible to efficiently manufacture a semiconductor device using a large SiC substrate with a diameter of more than 4 inches.

The present invention has been made in view of the above circumstances, and one object of the present invention is to provide a method for manufacturing a SiC crystal with a diameter of more than 4 inches which can be utilized as a semiconductor substrate.

The inventors of the present invention studied manufacturing of a SiC crystal with a diameter of more than 4 inches using a sublimation method in order to achieve the above object. As a result, the inventors found that, when the conventionally utilized sublimation method is used, there is a tendency that in-plane uniformity in crystal growth is reduced with an increase in the size of the SiC crystal. Since a SiC crystal having low in-plane uniformity has irregularities in its surface, it is not suitable as a semiconductor substrate. The inventors of the present invention earnestly investigated its cause, and arrived at a cause described below.

Conventionally, when a semiconductor crystal is grown on a surface of a seed substrate by the sublimation method, heating has been performed with a pressure within a growth container housing the seed substrate and a source material for the semiconductor crystal being maintained constant. This is based on a general idea that, in order to stabilize crystal growth, the pressure during the growth should be maintained constant. Under such a condition, a source gas generated within the growth container is dispersed within the growth container by thermal convection and diffusion. It is considered that the fully dispersed source gas uniformly adheres to the surface of the seed substrate, and thereby a homogeneous semiconductor crystal is fabricated.

However, when a SiC crystal is grown on a surface of a seed substrate, since a source gas has a low partial pressure, a growth container should have a reduced pressure atmosphere therein. Under such a condition, it is difficult to cause thermal convection within the growth container, and the source gas is dispersed within the growth container mainly by diffusion. In particular, when a SiC crystal with a diameter of more than 4 inches is manufactured, dispersion of the source gas within the growth container becomes insufficient. Thus, the source gas cannot uniformly adhere to the surface of the seed substrate with a large diameter, and as a result, growth of the SiC crystal becomes nonuniform in a plane.

Therefore, the inventors of the present invention further conducted intensive investigations to solve the above problem due to the above cause and manufacture a SiC crystal with a diameter of more than 4 inches which can be used as a semiconductor substrate, and finally completed the present invention.

Namely, the present invention is directed to a method for manufacturing a SiC crystal, including the steps of: placing a seed substrate and a source material for the SiC crystal within a growth container; and growing the SiC crystal with a diameter of more than 4 inches on a surface of the seed substrate by a sublimation method, in the step of growing, a pressure within the growth container being changed from a predetermined pressure, at a predetermined change rate.

According to the present invention, since the pressure within the growth container is changed from a predetermined pressure, at a predetermined change rate, fluctuation of a gas within the growth container can be forcibly generated. Thereby, the source material for the SiC crystal generated within the growth container is fully dispersed within the growth container, and can uniformly adhere to the surface of the seed substrate, and as a result, the SiC crystal can be uniformly grown in a plane of the seed substrate. Therefore, a SiC crystal with a diameter of more than 4 inches which has high in-plane uniformity and can be utilized as a semiconductor substrate can be manufactured.

Preferably, in the method for manufacturing the SiC crystal, in the step of growing, the predetermined pressure is not more than 5 kPa, and the predetermined change rate is not less than 0.1% and not more than 5% of the predetermined pressure.

Thereby, a source gas within the growth container can be dispersed more efficiently, and as a result, the in-plane uniformity of the fabricated SiC crystal can be further improved.

Preferably, in the method for manufacturing the SiC crystal, in the step of growing, a change rate of a temperature within the growth container is not more than 0.1% of a predetermined temperature.

Thereby, the source gas within the growth container can be dispersed more efficiently, and as a result, the in-plane uniformity of the fabricated SiC crystal can be further improved.

Preferably, in the method for manufacturing the SiC crystal, in the step of growing, the pressure within the growth container is changed once per minute or more.

Thereby, the source gas within the growth container can be dispersed more efficiently, and as a result, the in-plane uniformity of the fabricated SiC crystal can be further improved.

Preferably, in the method for manufacturing the SiC crystal, the SiC crystal is a single crystal.

According to the method for manufacturing the SiC crystal, a SiC crystal with high in-plane uniformity made of a single crystal can be easily manufactured.

As described above, according to the method for manufacturing the SiC crystal in accordance with the present invention, a SiC crystal with a diameter of more than 4 inches which can be utilized as a semiconductor substrate can be manufactured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing a method for manufacturing a SiC crystal in an embodiment of the present invention.

FIGS. 2(a) and 2(b) are schematic views for illustrating growth of the SiC crystal.

FIG. 3 is a graph showing changes in pressure in Example 1.

### DESCRIPTION OF THE PREFERRED EMBODIMENTS

Hereinafter, an embodiment of the present invention will be described with reference to the drawings. It is to be noted that, in the below-mentioned drawings, identical or corresponding parts will be designated by the same reference numerals, and the description thereof will not be repeated. Further, in the present specification, an individual plane is represented by ( ) a group plane is represented by {}, and a group orientation is represented by <>. In addition, a negative index is supposed to be crystallographically indicated by putting “-” (bar) above a numeral, but is indicated by putting the negative sign before the numeral in the present specification.

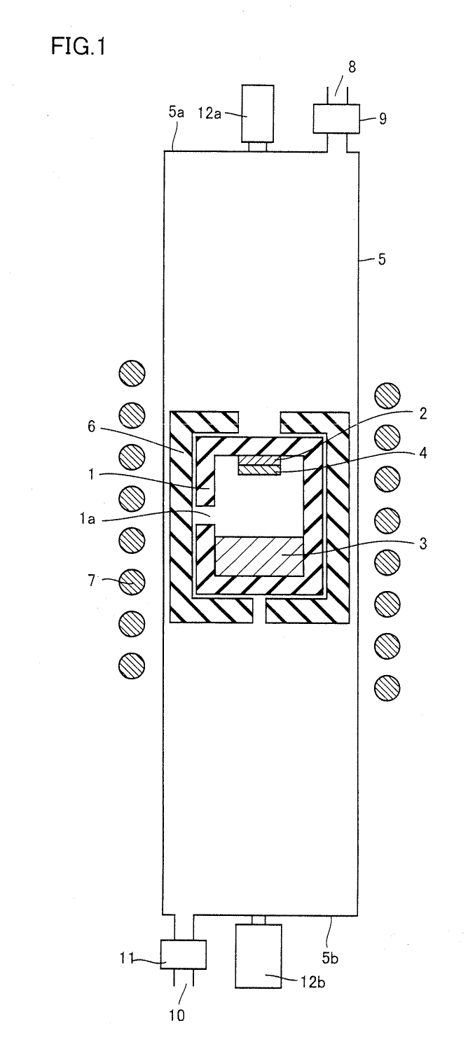

FIG. 1 is a schematic view showing a method for manufacturing a SiC crystal in an embodiment of the present invention. As shown in FIG. 1, the manufacturing method of the present invention includes the steps of placing a seed substrate 2 and a source material 3 for a SiC crystal within a growth container 1, and growing a SiC crystal 4 with a diameter of more than 4 inches on a surface of seed substrate 2 by a sublimation method. In particular, the present invention is characterized in that, in the step of growing, a pressure within growth container 1 is changed from a predetermined pressure, at a predetermined change rate.

### Crystal Manufacturing Apparatus

The above manufacturing method will be further described in detail. Firstly, a crystal manufacturing apparatus shown in FIG. 1 will be described to facilitate understanding of the above manufacturing method.

Referring to FIG. 1, the crystal manufacturing apparatus has a vertical crucible 5. Growth container 1 is placed at a central portion inside crucible 5, and a heated body 6 is provided around growth container 1 to allow ventilation between the inside and the outside of growth container 1. A high-frequency heating coil 7 for heating heated body 6 is placed at a central portion outside crucible 5.

A gas introduction port 8 for allowing a gas to flow into crucible 5 is provided at an upper end portion of crucible 5, and a flow rate controller 9 for controlling an introduction amount of the gas is provided at gas introduction port 8. Further, a gas exhaust port 10 for allowing a gas within crucible 5 to flow out is provided at a lower end portion of crucible 5, and a flow rate controller 11 for controlling an exhaust amount of the gas is provided at gas exhaust port 10. Furthermore, radiation thermometers 12a, 12b for measuring temperatures of an upper surface and a lower surface of growth container 1 are provided on a ceiling surface 5a and a bottom surface 5b of crucible 5, respectively.

Since a ventilation port 1a is provided in growth container 1, and heated body 6 provided around growth container 1 is provided to allow ventilation between the inside and the outside of growth container 1 as described above, a flow of the gas within crucible 5 is also reflected within growth container 1. The position of ventilation port 1a is not particularly limited, and ventilation port 1a may be provided at any position which allows seed substrate 2 and source material 3 to be placed within growth container 1 and prevents flowing-out of source material 3 through ventilation port 1a, and the like.

Further, for example, in a case where growth container 1 is made of graphite, it is not necessary to provide ventilation port 1a. This is because, in this case, growth container 1 has a fine porous wall, which allows ventilation between the inside and the outside of growth container 1 without providing ventilation port 1a. Further, in this case, the gas can enter and exit through the entire surface of growth container 1, unlike the entry and exit of the gas through ventilation port 1a. Accordingly, fluctuation of the gas within crucible 5 is more likely to be stably reflected within growth container 1, and an unwanted, unexpected flow of the gas is less likely to be generated. Therefore, such a case is more preferable.

### Method for Manufacturing SiC Crystal

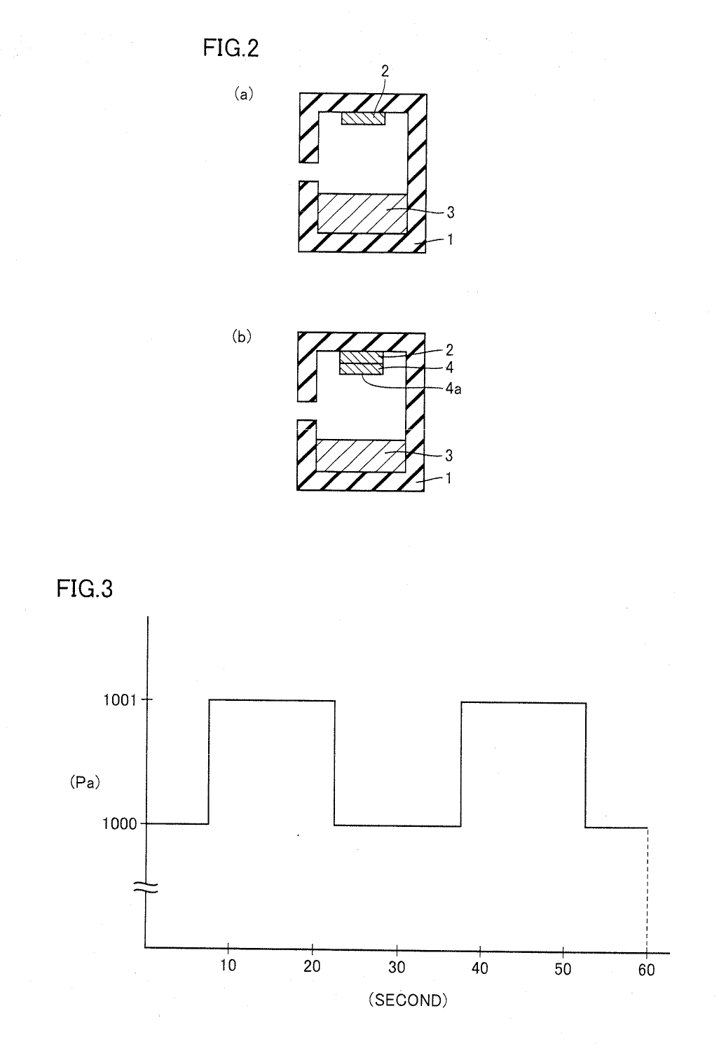

Next, a method for manufacturing the SiC crystal in the present embodiment using the above crystal manufacturing apparatus will be described with reference to FIGS. 1 and 2. FIGS. 2(a) and 2(b) are schematic views for illustrating growth of the SiC crystal.

Firstly, seed substrate 2 and source material 3 for the SiC crystal are placed within growth container 1. In FIG. 1, seed substrate 2 is installed on a ceiling surface of growth container 1. A method for installing seed substrate 2 is not particularly limited, and, for example, seed substrate 2 may be directly fixed to the ceiling surface, or a pedestal may be provided on the ceiling surface and then seed substrate 2 may be fixed to the pedestal. Further, source material 3 is housed at a bottom portion within growth container 1.

Seed substrate 2 is made of a SiC crystal, preferably has a hexagonal crystal structure, and more preferably is 4H—SiC or 6H—SiC. Further, a surface of seed substrate 2, that is, its surface on which SiC crystal 4 is to be grown, preferably has a low-index plane orientation. For example, in the case of a hexagonal system, the surface may correspond to a (0001) plane, a (000-1) plane, a (10-10) plane, a (11-20) plane, or the like. Among them, the (0001) plane is preferable from the viewpoint of crystallinity of grown SiC crystal 4. Further, the surface preferably has an off angle from such a crystal plane as appropriate. As a concrete example, the surface preferably has an off angle of not less than −5° and not more than 5° with respect to the (0001) plane in a <11-20> direction. Furthermore, seed substrate 2 made of the SiC crystal may contain an impurity, and an impurity concentration is, for example, not less than 5×10¹⁶ cm⁻³ and not more than 5×10¹⁹ cm⁻³.

The shape of a main surface of seed substrate 2 is not particularly limited, and any shape in conformity with a desired shape of the crystal may be used. For example, the main surface has the shape of a circle, a rectangle, or a strip, and preferably has the shape of a circle. Further, in the present embodiment, in order to manufacture SiC crystal 4 with a diameter of not less than 4 inches, seed substrate 2 preferably has a diameter of at least more than 4 inches.

Source material 3 is a source material for growing SiC crystal 4, and is not particularly limited as long as it generates a source gas such as SiC₂ gas or Si₂C gas. Further, its shape and placement are not particularly limited either as long as the source gas can reach the surface of seed substrate 2. For example, from the viewpoint of ease of handling and ease of preparation of a source material, it is preferable to use SiC powder. The SiC powder can be obtained, for example, by pulverizing a SiC polycrystal. Further, to grow SiC crystal 4 doped with an impurity such as nitrogen and phosphorus, the impurity may be mixed with source material 3.

Next, as shown in FIGS. 2(a) and 2(b), SiC crystal 4 with a diameter of more than 4 inches is grown on the surface of seed substrate 2 by the sublimation method. Specifically, in this step, an inert gas is introduced from gas introduction port 8 into crucible 5, and the gas within crucible 5 is exhausted from gas exhaust port 10.

On this occasion, a pressure within crucible 5 is controlled by controlling the introduction amount and the exhaust amount using flow rate controllers 9, 11. Although the pressure within crucible 5 is changed as appropriate depending on the temperature of an atmosphere within growth container 1, it is at least controlled to be not more than 5 kPa. Since ventilation can be provided between the inside of crucible 5 and the inside of growth container 1, a pressure within growth container 1 is also reduced to not more than 5 kPa by the control of the pressure described above. It is to be noted that, as the inert gas, for example, an inert gas containing at least one type selected from the group consisting of argon, helium, and nitrogen can be introduced.

Further, in this step, high-frequency heating coil 7 heats heated body 6 within crucible 5. Thereby, the temperature of heated body 6 is increased to a predetermined temperature, and thus the temperature within growth container 1 surrounded by heated body 6 is also increased to the predetermined temperature. Although a preferable temperature within growth container 1 is changed as appropriate depending on the pressure within crucible 5, the temperature within growth container 1 is heated at least to a temperature of not less than 2000° C. and not more than 2500° C. It is to be noted that, in order to efficiently direct the source gas generated from source material 3 toward the surface of seed substrate 2 in the sublimation method, growth container 1 is heated to be provided with a temperature gradient in which the temperature within growth container 1 decreases from a source material 3 side (a lower side within growth container 1) to a seed substrate 2 side (an upper side within growth container 1).

Subsequently, in this step, vapor deposition of SiC crystal 4 by the sublimation method is started at the time when the pressure of the atmosphere within growth container 1 attains a predetermined pressure of not more than 5 kPa (growth pressure), the temperature of the atmosphere within growth container 1 reaches a temperature range of not less than 2000° C. and not more than 2500° C. (growth temperature), and the source gas is generated from source material 3 by sublimation of the SiC powder. Specifically, for example, if the lower side within growth container 1 has a growth temperature of 2400° C., vapor deposition of SiC crystal 4 is started upon the above pressure reaching 1 kPa.

Here, in the present invention, in this step, the pressure within crucible 5 is controlled such that the pressure of the atmosphere within growth container 1 is changed from the above predetermined pressure, at a predetermined change rate. Such a change in pressure can be implemented, for example, by intermittently introducing the gas into crucible 5 using flow rate controllers 9, 11 to change the pressures within crucible 5 and growth container 1. Further, such a change can also be implemented by PID control. In addition, instead of control to forcibly change the pressure, the pressure may be changed by adjusting a control parameter.

As a result of the pressure of the atmosphere within growth container 1 being changed from the above predetermined pressure, at a predetermined change rate, fluctuation of the gas is generated within growth container 1. Thereby, the source gas can be fully diffused within growth container 1, and the diffused source gas can uniformly adhere to the surface of seed substrate 2. Therefore, growth of SiC crystal 4 on the surface of seed substrate 2 becomes uniform in a plane, and thus in-plane uniformity of SiC crystal 4 can be improved.

It is to be noted that the in-plane uniformity of SiC crystal 4 can be measured by measuring thicknesses of SiC crystal 4 in a crystal growth direction at respective positions in a surface 4a thereof. Namely, the in-plane uniformity is high if the above thicknesses are constant at the respective positions in surface 4a, and the in-plane uniformity is low if the above thicknesses vary at the respective positions in surface 4a.

Preferably, the above predetermined pressure is not more than 5 kPa. Thereby, the source gas can be efficiently generated. More preferably, the above predetermined pressure is not more than 1 kPa. Further, in this step, the pressure within crucible 5 is preferably controlled to be changed from the predetermined pressure, at a change rate of not less than 0.1% and not more than 5%. In this case, for example, if the temperature within growth container 1 is 2400° C. and the pressure within growth container 1 is 1 kPa, the pressure is changed in a range of not less than 1 Pa and not more than 50 Pa. The pressure may be changed to be decreased or increased from the predetermined pressure, by not less than 0.1% and not more than 5%.

By setting the change rate of the growth pressure to not less than 0.1%, the in-plane uniformity of the SiC crystal can be improved. In addition, by setting the change rate of the growth pressure to not more than 5%, a change in polytype of the SiC crystal and polycrystallization of the SiC crystal can be suppressed during the growth of the SiC crystal. Therefore, by changing the growth pressure at a change rate of not less than 0.1% and not more than 5% of the growth pressure in this step, a SiC crystal made of a single crystal can be manufactured in a good yield.

Further, in this step, a change rate of the temperature within growth container 1 is preferably not more than 0.1% of the above predetermined temperature. By controlling the change rate of the temperature to be not more than 0.1%, a change in polytype of the SiC crystal and polycrystallization of the SiC crystal can be further suppressed.

Further, in this step, the pressure within growth container 1 is preferably changed once per minute or more. Here, the expression “changed once per minute” means that the pressure is increased and decreased once per minute. By changing the pressure within growth container 1 once per minute or more, uniform dispersion of the source gas can be promoted more effectively, and thus the in-plane uniformity of the SiC crystal can be further improved.

One example of the method for manufacturing the SiC crystal as an example of the present invention has been described with reference to FIGS. 1 and 2. With the above manufacturing method, a SiC crystal with a diameter of not less than 4 inches having high in-plane uniformity can be manufactured. Such a SiC crystal can be used as a semiconductor substrate used to manufacture a semiconductor device.

Further, the SiC crystal may be a polycrystal or a single crystal. In particular, by setting the change rate of the pressure to not less than 0.1% and not more than 5%, a high-quality SiC single crystal can be easily manufactured in a high yield. Furthermore, by setting the change rate of the temperature within growth container 1 to not more than 0.1%, and/or performing control such that the pressure within growth container 1 is changed once per minute or more, a high-quality SiC single crystal can be easily manufactured in a higher yield. The above SiC single crystal can be grown such that, for example, it has an off angle of not more than 5° with respect to the surface of seed substrate 2.

### EXAMPLES

The present invention will be described more concretely with reference to examples and comparative examples. However, the present invention is not limited by these examples and comparative examples.

(Consideration 1: Change Rate of Pressure)

A SiC crystal of Example 1 was manufactured using the crystal manufacturing apparatus shown in FIG. 1. Firstly, high-purity SiC powder was allowed to fill growth container 1 made of graphite to form a flat surface, and used as a source material. The total amount of the used source material was 2000 g. Then, a seed substrate was placed on the ceiling surface within growth container 1. As the seed substrate, a 4H—SiC single crystal with a diameter of 150 mm (6 inches) and a thickness of 1 mm, having a main surface in the shape of a circle, fabricated by a known method, was used. The seed substrate had the (0001) plane as the main surface, and the off angle was 4°.

Next, He gas was introduced from gas introduction port 8 at the upper end portion of crucible 5 to reduce a pressure of an atmosphere within crucible 5 to 1000 Pa. At the same time, an atmosphere within growth container 1 was heated to obtain a temperature of 2350° C., using high-frequency heating coil 7.

Here, the atmosphere within growth container 1 was heated to form a temperature gradient in which the temperature within growth container 1 linearly decreased from the source material to the seed substrate. Due to the temperature gradient, a lower portion of growth container 1 had a temperature (growth temperature) of 2350° C., and an upper portion of growth container 1 had a temperature of 2200° C., which were measured with radiation thermometers 12a and 12b. Further, when a change in growth temperature was measured with radiation thermometer 12b, it was found that the change was less than 0.1%.

Subsequently, at the time when the atmosphere within growth container 1 had a temperature under the above temperature gradient and a pressure of 1000 Pa, growth pressure within crucible 5 was changed using flow rate controllers 9 and 11 such that the pressure of the atmosphere within growth container 1 would be changed from 1000 Pa, by 0.1%, twice per minute. The above change exhibited a behavior shown in FIG. 3. With the growth pressure being periodically changed as shown in FIG. 3, and with the above temperature gradient being maintained, a SiC crystal was grown for 250 hours, and thereafter the temperature within growth container 1 was cooled to room temperature.

Further, as Example 2, a SiC crystal was grown by the same method as that in Example 1, except that the pressure within crucible 5 was changed such that the pressure of the atmosphere within growth container 1 would be changed from 1000 Pa by 1%. As Example 3, a SiC crystal was grown by the same method as that in Example 1, except that the pressure within crucible 5 was changed such that the pressure of the atmosphere within growth container 1 would be changed from 1000 Pa by 3%. As Example 4, a SiC crystal was grown by the same method as that in Example 1, except that the pressure within crucible 5 was changed such that the pressure of the atmosphere within growth container 1 would be changed from 1000 Pa by 5%.

Furthermore, as Comparative Example 1, a SiC crystal was grown by the same method as that in Example 1, except that the pressure within crucible 5 was changed such that the pressure of the atmosphere within growth container 1 would be changed from 1000 Pa by 0.05%. As Comparative Example 2, a SiC crystal was grown by the same method as that in Example 1, except that the pressure within crucible 5 was changed such that the pressure of the atmosphere within growth container 1 would be changed from 1000 Pa by 8%. As Comparative Example 3, a SiC crystal was grown by the same method as that in Example 1, except that the pressure within crucible 5 was changed such that the pressure of the atmosphere within growth container 1 would be changed from 1000 Pa by 10%.

(Evaluation)

In-plane uniformity of each of the SiC crystals of Examples 1 to 4 and Comparative Examples 1 to 3 was evaluated.

Specifically, in each SiC crystal, the thickness of the center of the (0001) plane as the main surface was measured, and, with the measurement position being shifted from the main surface both in a <11-20> direction and in a <10-10> direction at a pitch of 1 mm, thicknesses at respective positions were measured. Then, in-plane nonuniformity (%) was calculated from nonuniformity in thickness of the SiC crystal in each direction. Further, each SiC crystal was sliced along the (0001) plane, polished, and thereafter etched using molten KOH to observe presence or absence of polycrystallization, presence or absence of a change in polytype, and presence or absence of a stacking fault. Table 1 shows results.

TABLE 1

| | Comparative | | | | | Comparative | Comparative |
|---|---|---|---|---|---|---|---|
| | Example 1 | Example 1 | Example 2 | Example 3 | Example 4 | Example 2 | Example 3 |
| Growth Temperature (° C.) | 2350 | 2350 | 2350 | 2350 | 2350 | 2350 | 2350 |
| Growth Pressure (Pa) | 1000 | 1000 | 1000 | 1000 | 1000 | 1000 | 1000 |
| Pressure Change (%) | 0.05 | 0.1 | 1 | 3 | 5 | 8 | 10 |
| Change Cycle | 2 | 2 | 2 | 2 | 2 | 2 | 2 |
| (times/minute) | | | | | | | |
| Central Portion Thickness | 30 | 30 | 30 | 29 | 28 | 23 | 18 |
| (mm) | | | | | | | |
| In-plane Nonuniformity in | 28 | 12 | 10 | 8 | 5 | 3 | 2 |
| <11-20> direction (%) | | | | | | | |
| In-plane Nonuniformity in | 23 | 10 | 8 | 6 | 3 | 2 | 2 |
| <10-10> direction (%) | | | | | | | |
| Presence/Absence of | Absent | Absent | Absent | Absent | Absent | Absent | Present |
| Polycrystallization | | | | | | | |
| Presence/Absence of | Absent | Absent | Absent | Absent | Absent | Present | Present |
| Change in Polytype | | | | | | | |
| Presence/Absence of | Present | Absent | Absent | Absent | Absent | Absent | Absent |
| Stacking Fault | | | | | | | |

Referring to Table 1, it was found that, in Examples 1 to 4, i.e., in the cases where the pressure change was not less than 0.1% and not more than 5%, the SiC crystals had low in-plane nonuniformity of not more than 12%; when compared with the SiC crystal of Comparative Example 1 having a pressure change of 0.05%. Further, although a stacking fault was observed in the SiC crystal of Comparative Example 1, no stacking fault was observed in the SiC crystals of Examples 1 to 4.

Furthermore, the SiC crystals of Examples 1 to 4 had a 4H polytype only, whereas the SiC crystals of Comparative Examples 2 and 3 had both a 4H polytype and a 6H polytype. In addition, the SiC crystals of Examples 1 to 4 were each composed of a single crystal only, whereas the SiC crystal of Comparative Example 3 had a polycrystallized region.

(Consideration 2: Change Rate of Temperature)

As Example 5, a SiC crystal was manufactured by the same method as that in Example 2, except that growth temperature within growth container 1 was changed at a change rate of 0.1%. It is to be noted that the growth temperature was changed twice per minute to exhibit the same behavior as that in the case of changing the pressure, and the temperature gradient within growth container 1 was maintained. Similarly, as Examples 6 and 7, SiC crystals were manufactured by the same method as that in Example 2, except that the growth temperature within growth container 1 was changed by 0.3% and 0.5%, respectively.

(Evaluation)

For each of the SiC crystals of Examples 5 to 7, in-plane nonuniformity (%) was calculated, and presence or absence of polycrystallization, presence or absence of a change in polytype, and presence or absence of a stacking fault were observed, by the same method as that in Example 2. Table 2 shows results. It is to be noted that Table 2 also shows the result of Example 2 to facilitate evaluation on the change rate of the temperature.

TABLE 2

| | Example 2 | Example 5 | Example 6 | Example 7 |
|---|---|---|---|---|
| Growth Temperature | 2350 | 2350 | 2350 | 2350 |
| (° C.) | | | | |
| Growth Pressure (Pa) | 1000 | 1000 | 1000 | 1000 |
| Pressure Change (%) | 1 | 1 | 1 | 1 |
| Temperature Change (%) | not more | 0.1 | 0.3 | 0.5 |
| | than 0.1 | | | |
| Change Cycle | 2 | 2 | 2 | 2 |
| (times/minute) | | | | |
| Central Portion Thickness | 30 | 30 | 28 | 27 |
| (mm) | | | | |
| In-plane Nonuniformity | 10 | 10 | 12 | 15 |
| in <11-20> direction (%) | | | | |
| In-plane Nonuniformity | 8 | 8 | 10 | 12 |
| in <10-10> direction (%) | | | | |
| Presence/Absence of | Absent | Absent | Absent | Present |
| Polycrystallization | | | | |
| Presence/Absence of | Absent | Absent | Present | Present |
| Change in Polytype | | | | |
| Presence/Absence of | Absent | Absent | Absent | Absent |
| Stacking Fault | | | | |

Referring to Table 2, in the cases where the temperature change was not more than 0.1% (Examples 2 and 5), none of polycrystallization, a change in polytype, and a stacking fault was observed, whereas in the cases where the temperature change was 0.3% and 0.5% (Examples 6 and 7), a change in polytype and/or polycrystallization was observed. From this consideration, it was found that yield of a SiC single crystal which can be used as a semiconductor substrate is improved by setting the temperature change to not more than 0.1%.

(Consideration 3: Frequency of Pressure Change)

As Example 8, a SiC crystal was grown by the same method as that in Example 2, except that the pressure within crucible 5 was changed such that the pressure of the atmosphere within growth container 1 would be changed once per minute. As Example 9, a SiC crystal was grown by the same method as that in Example 2, except that the pressure within crucible 5 was changed such that the pressure of the atmosphere within growth container 1 would be changed 0.5 times per minute (i.e., once per two minutes). As Example 10, a SiC crystal was grown by the same method as that in Example 2, except that the pressure within crucible 5 was changed such that the pressure of the atmosphere within growth container 1 would be changed 0.25 times per minute (i.e., once per four minutes).

(Evaluation)

For each of the SiC crystals of Examples 8 to 10, in-plane nonuniformity (%) was calculated, and presence or absence of polycrystallization, presence or absence of a change in polytype, and presence or absence of a stacking fault were observed, by the same method as that in Example 2. Table 3 shows results. It is to be noted that Table 3 also shows the result of Example 2 to facilitate evaluation on the frequency of the pressure change.

TABLE 3

| | Example 2 | Example 8 | Example 9 | Example 10 |
|---|---|---|---|---|
| Growth Temperature | 2350 | 2350 | 2350 | 2350 |
| (° C.) | | | | |
| Growth Pressure (Pa) | 1000 | 1000 | 1000 | 1000 |
| Pressure Change (%) | 1 | 1 | 1 | 1 |
| Change Cycle | 2 | 1 | 0.5 | 0.25 |
| (times/minute) | | | | |
| Central Portion | 30 | 30 | 30 | 30 |
| Thickness (mm) | | | | |
| In-plane Nonuniformity | 10 | 12 | 18 | 23 |
| in <11-20> direction (%) | | | | |
| In-plane Nonuniformity | 8 | 10 | 15 | 19 |
| in <10-10> direction (%) | | | | |
| Presence/Absence of | Absent | Absent | Absent | Absent |
| Polycrystallization | | | | |
| Presence/Absence of | Absent | Absent | Absent | Absent |
| Change in Polytype | | | | |
| Presence/Absence of | Absent | Absent | Present | Present |
| Stacking Fault | | | | |

Referring to Table 3, in the cases where the frequency of the pressure change was once per minute or more (Examples 2 and 8), none of polycrystallization, a change in polytype, and a stacking fault was observed, whereas in the cases where the frequency of the pressure change was 0.5 times per minute or less (Examples 9 and 10), a stacking fault was observed. Further, in the cases where the frequency of the pressure change was 0.5 times per minute or less, in-plane nonuniformity tended to be increased. From this consideration, it was found that yield of a SiC single crystal which can be used as a semiconductor substrate is improved by setting the frequency of the pressure change to once per minute or more.

The present invention has a possibility to be able to be utilized for a method for manufacturing a high-quality SiC crystal for a semiconductor substrate in a good yield.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide crystal, comprising the steps of:
placing a seed substrate and a source material for the silicon carbide crystal within a growth container; and
growing the silicon carbide crystal with a diameter of more than 4 inches on a surface of said seed substrate by a sublimation method,
in said step of growing, a pressure within said growth container being changed from a predetermined pressure, at a predetermined change rate.

2. The method for manufacturing the silicon carbide crystal according to claim 1, wherein, in said step of growing, said predetermined pressure is not more than 5 kPa, and said predetermined change rate is not less than 0.1% and not more than 5% of said predetermined pressure.

3. The method for manufacturing the silicon carbide crystal according to claim 1, wherein, in said step of growing, a change rate of a temperature within said growth container is not more than 0.1% of a predetermined temperature.

4. The method for manufacturing the silicon carbide crystal according to claim 1, wherein, in said step of growing, the pressure within said growth container is changed once per minute or more.

5. The method for manufacturing the silicon carbide crystal according to claim 1, wherein said silicon carbide crystal is a single crystal.
